(19) United States
(12) Patent Application Publication
(10) Pub. No.: US 2026/0128103 A1
(43) Pub. Date: May 7, 2026

(54) MEMORY DEVICE AND METHOD OF PROVIDING AN ADDRESS PAGE OF A REGISTER ACCESSIBLE TO EACH CLIENT

(71) Applicant: SK hynix Inc., Icheon-si (KR)

(72) Inventor: Jin Yong SEONG, Icheon-si (KR)

(21) Appl. No.: 19/183,051

(22) Filed: Apr. 18, 2025

(30) Foreign Application Priority Data
Nov. 7, 2024 (KR) 10-2024-0157206

(51) Int. Cl. G11C 16/22; G11C 16/10; G11C 16/26

(52) U.S. Cl. CPC G11C 16/22; G11C 16/102; G11C 16/26

(57) ABSTRACT

A memory device may include a memory cell array, a register group and a logic controller. The register group may include a plurality of registers configured to store set values used for various operations on the memory cell array, and a specific register including a first address information of at least one accessible register selected from the plurality of registers. The logic controller may compare second address information and the first address information, and allow or block access of the accessible register based on the comparison result. The second address is received with a register access command from an external device.

### CROSS-REFERENCES TO RELATED APPLICATION

The present application claims priority under 35 U.S.C. § 119(a) to Korean patent application number 10-2024-0157206, filed on Nov. 7, 2024, in the Korean Intellectual Property Office, which is incorporated herein by reference in its entirety.

### BACKGROUND

### 1. Technical Field

Example embodiments relate to a memory device, and more particularly, relate to a memory device and method of providing an address range of a register accessible to each client.

### 2. Related Art

A memory cell array of a memory device may store information for operating the memory device such as a set value in addition to user input information. The set value may include a condition or other information which sets the operation of the memory device. For example, the set condition for the operation of the memory device may include a power supply voltage and power-up time information used for a program operation, a read operation and an erase operation. The other information may include bad information (e.g., bad column address information, bad block address information, etc.), number of program/erase performances (P/E Cycle), etc.

The set information may be stored as non-volatile data in the memory cell array of the memory device. When the memory device may be powered on, the data may be read out of the memory cell array and stored in a register. For example, one register may include a single set of information. Accordingly, there may be more than one register for controlling various operations of the memory device.

Among a plurality of registers in a memory device, there are a very small number of registers that are commonly accessible to all clients, and whose settings may be changed. However, to prevent problems such as malfunctions and failures, access to most registers is not allowed.

### SUMMARY

Example embodiments provide a memory device and method of providing an address range of a register accessible to each client.

According to example embodiments, there may be provided a memory device. The memory device may include a memory cell array, a register group and a logic controller. The register group may include a plurality of registers configured to store set values used for operations of the memory cell array, the plurality of registers comprising a specific register including first address information of at least one accessible register selected from the plurality of registers. The logic controller may compare second address information to the first address information, and to allow or block access of the accessible register based on the comparison result. The second address information is input with a register access command from an external device.

According to example embodiments, there may be provided a method of operating a memory device. Set values used for operations of the memory device may be read from a memory cell array. The set values are stored in a plurality of registers. First address information of at least one accessible register of the plurality of registers is stored in a specific register. The first address information compares with second address information when a register access command and the second address information are received from an external device. Access of the accessible register is allowed or blocked based on the comparison result.

According to example embodiments, there may be provided a memory device. The memory device may a plurality of registers configured to store set values used for operations of the memory device, and a specific register including first address information of at least one accessible register of the plurality of registers. The logic controller may be configured to compare the first address information with second address information, and to allow access of the accessible register, when the first address information matches the second address information. The second address information is input with a register access command provided from an external device

According to example embodiments, the logic controller is configured to compare a first password with a second password, and to allow the access of the accessible register when the first password is matched with the second password. The first password is a password provided from the external device, and the second password is a registered password.

### BRIEF DESCRIPTION OF THE DRAWINGS

The above and another aspects, features and advantages of the subject matter of the present disclosure will be more easily understood from the following detailed description taken in conjunction with the accompanying drawings, in which:

FIG. 1 illustrates an exemplary embodiment of a memory device ;

FIG. 2 illustrates a logic controller of the embodiment of FIG. 1;

FIG. 3 illustrates locking operations of a locking controller of the embodiment of FIG. 2;

FIG. 4 illustrates accessible register address information of the embodiment of FIG. 2;

FIG. 5 is a flow chart illustrating a method of operating a memory device according to an exemplary embodiment;

FIG. 6 is a flow chart illustrating detailed steps of S580 of the embodiment of FIG. 5;

FIG. 7 is a flow chart illustrating a method of locking an accessible register by a client according to an exemplary embodiment; and

FIG. 8 is a flow chart illustrating a method of accessing an accessible register according to an exemplary embodiment.

### DETAILED DESCRIPTION

Embodiments of the present technology will now be described in more detail with reference to the accompanying drawings.

Embodiments of the present disclosure are hereinafter described in detail, with reference to the drawings, to facilitate practice by one of ordinary skill in the art to which the disclosure belongs. However, the present disclosure may be implemented in many different forms and is not limited to the embodiments described herein. In connection with the description of the drawings, the same or similar reference numerals may be used for the same or similar components. Further, in the drawings and related descriptions, the descriptions of well-known features and operations may be omitted for clarity and brevity.

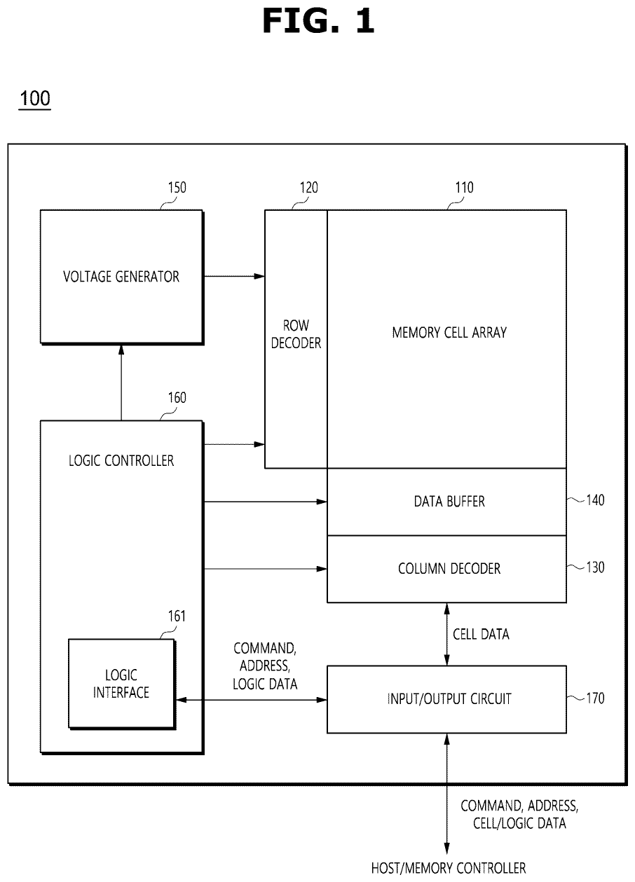

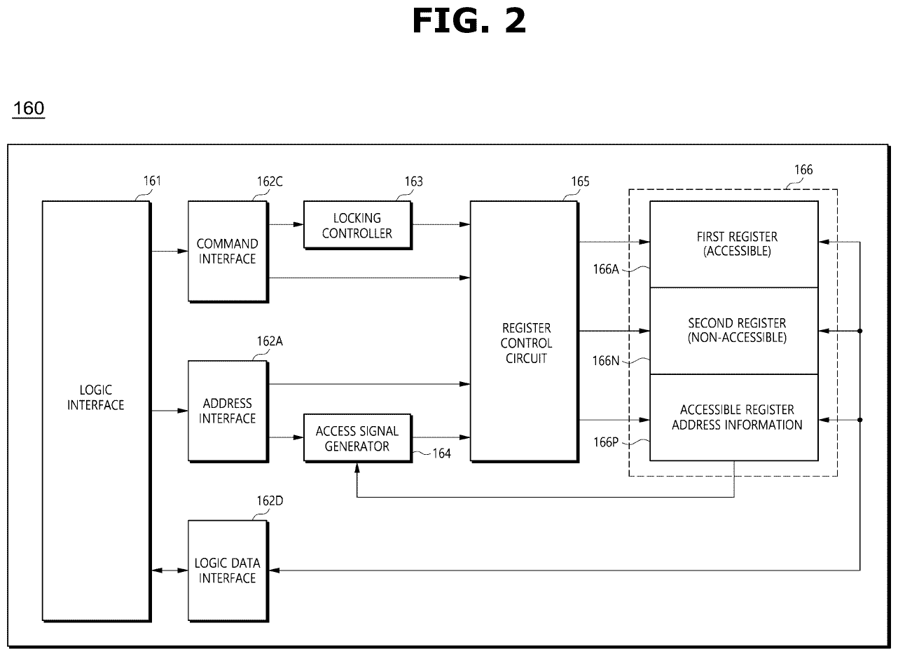

FIG. 1 illustrates an example of a memory device 100 according to an embodiment of the present disclosure, and FIG. 2 illustrates an example of a logic controller 160 of the embodiment of FIG. 1.

Referring to FIG. 1, a memory device 100 may include a memory cell array 110, a row decoder 120, a column decoder 130, a data buffer 140, a voltage generator 150, a logic controller 160 and an input/output circuit 170.

The memory cell array 110 may include a plurality of memory cells (not shown). Each of the memory cells may be disposed in a region where a plurality of bit lines BL and a plurality of word lines WL may intersect with each other. The memory cell array 110 may include a plurality of memory blocks (not shown). The plurality of memory blocks may include a plurality of pages (not shown), respectively.

For example, a memory cell in the memory cell array 110 may be a single level cell (SLC) configured to store one bit, a multi-level cell (MLC) configured to store two bits of data, a triple level cell (TLC) configured to store three bits of data, or a quadruple level cell (QLC) configured to store four bits of data. The memory cell array 110 may include at least one of the single level cell, the multi-level cell, the triple level cell and the quadruple level cell. For example, the memory cell array 110 may include a plurality of memory cells in a two-dimensional horizontal structure. Alternately, the memory cell array 110 may include a plurality of memory cells in a three-dimensional vertical structure.

The memory cell array 110 of example embodiments may include regions (or blocks) configured to store set values used for various operations of the memory device 100. The set values may include a set condition or other information related to the operation of the memory device. For example, the set condition may include voltage information and pulse information used for a program operation, a read operation and an erase operation, respectively. Other information may include bad information (e.g., bad column address information, bad block address information, etc.), program/erase performance count (P/E Cycle) information, etc.

When the memory device 100 is powered on, the set values stored in the memory cell array 110 may be read from the memory cell array 110 and stored in registers 166A, 166N and 166P in FIG. 2. The memory device 100 may perform operations related to requests provided from an external device using the set values stored in the registers 166A, 166N and 166P.

The row decoder 120 may be electrically coupled to the memory cell array 110 through the word lines WL. The row decoder 120 may be operated under control of the logic controller 160. The row decoder 120 may decode a low address provided by the external device, such as a host (not shown) or a memory controller (not shown). The row decoder 120 may select and drive at least one of the word lines WLs based on a decoding result. The row decoder 120 may provide a word line voltage provided from the voltage generator 150 to a selected word line WL.

The column decoder 130 may be operated under control of the logic controller 160. The column decoder 130 may decode a column address provided from a host (not shown) or a memory controller (not shown). The column decoder 130 may select and drive at least one bit line of the bit lines BL based on a decoding result.

The data buffer 140 may be configured to temporarily store write data provided from the host or the memory controller and to be stored in the memory cell array 110, or read data read from the memory cell array 110 and provided to the host or the memory controller. The data buffer 140 may be operated under control of the logic controller 160.

The voltage generator 150 may generate a voltage used for internal operations of the memory device 100. The voltage generator 150 may generate voltages used for the internal operations of the memory device 100 using power applied from the host. The voltage generator 150 may provide the voltages to the memory cell array 110, the logic controller 160, and the like. The voltages generated by the voltage generator 150 may be applied to the memory cells of the memory cell array 110.

The logic controller 160 may control various operations of the memory device 100 based on control signals provided from the host or the memory controller. For example, the logic controller 160 may control operations of a peripheral circuit in the memory device 100 such that a read operation, a write operation and an erase operation may be performed on the memory cell array 110 based on a read command, a write command and an erase command provided by the host or the memory controller. The peripheral circuit may include the row decoder 120, column decoder 130, and data buffer 140.

The input/output circuit 170 may be configured to receive a command, an address and data provided by the host or the memory controller, or to provide data read from the memory cell array 110 to the host or the memory controller.

The input/output circuit 170 may output logic data among the commands, the addresses and the data provided by the host or memory controller to a logic interface 161 of the logic controller 160. The input/output circuit 170 may output cell data to the data buffer 140. In example embodiments, the logic data may represent register set values, and the cell data may represent typical user data stored in the memory cell array 110.

The input/output circuit 170 may output the logic data provided from the logic interface 161 of the logic controller 160 and the cell data provided from the data buffer 140 to the host or the memory controller. The input/output circuit 170 may be operated under the control of the logic controller 160.

Referring to FIG. 2, the logic controller 160 of the memory device 100 of FIG. 1 may include a logic interface 161, a command interface 162C, an address interface 162A, a logic data interface 162D, a locking controller 163, an access signal generator 164, a register control circuit 165 and a register group 166.

The logic interface 161 may be configured to receive signals, such as the commands, addresses and data output from the input/output circuit 170, as shown in FIG. 1. The logic interface 161 may transmit the signals received from the input/output circuit 170 to corresponding interfaces based on types of the signals. For example, the types of signals may include the commands, the addresses and the data.

The logic interface 161 may transmit the commands to the command interface 162C, the addresses to the address interface 162A, and the logic data to the logic data interface 162D from among the signals received from the input/output circuit 170. In example embodiments, “command” may refer to a register access command, “address” may refer to a register address, and “logic data” may refer to register data (or a register set value).

For clarity, the terms “register access command,” “register address,” and “register data” will be used hereinafter instead of “command,”“address,”and “data”.

The command interface 162C may be configured to transmit the register access commands received from the logic interface 161 to the locking controller 163 and the register control circuit 165, respectively.

The address interface 162A may be configured to transmit the register addresses received from the logic interface 161 to the access signal generator 164 and the register control circuit 165, respectively.

The logic data interface 162D may be configured to transmit the register data received from the logic interface 161 to the register group 166.

The locking controller 163 may be configured to compare an input password with a registered password. The locking controller 163 may output at least one of a first signal indicating that access of the accessible register is permitted and a second signal indicating that access of the accessible register is not permitted or blocked, to the register control circuit 165 based on the comparison result.

When the password is input to locking controller 163, the password may be input by a register access command which includes the password or a separate authentication process. A typical password authentication process may be implemented as known in the art.

Further, the locking controller 163 may be configured to lock access of the accessible register. In example embodiments, the locking controller 163 may determine whether a locking command and a password to be registered are received from an external device. If it is determined that the locking command and the password to be registered are received, the locking controller 163 may register the received password as a password for the accessible register.

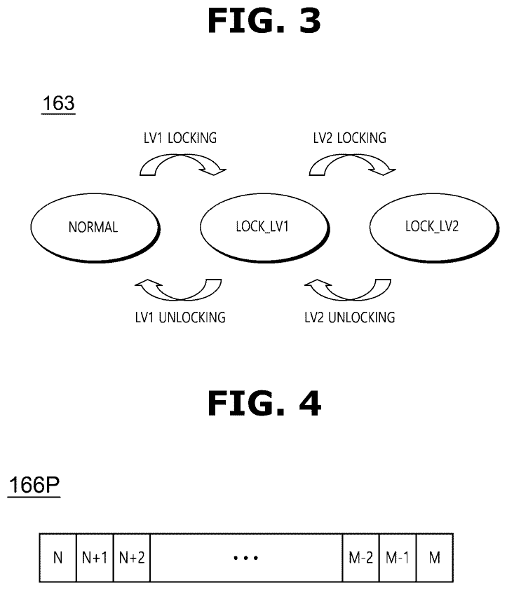

In example embodiments, the locking controller 163 may lock access of the accessible register in two steps, as shown in FIG. 3. For example, the locking controller 163 may register or set the first password for the accessible register during a manufacturing stage or a testing stage, and the second password for the accessible register may be registered or set by a client.

Specifically, the first password may be preset by hard coding the first password during the manufacturing stage or the testing stage. The second password may be set by the locking operations described above. In this case, the second password may be stored in a separate register (not shown) included in the locking controller 163, but embodiments are not limited thereto. The second password set by the locking command may be changed and reset as required by the client.

In some embodiments, both the first password and the second password for the accessible register may be set by the locking command input from the client. In this case, an initial password for the accessible register may be preset by hard coding the initial password during the manufacturing stage or the test stage.

Accordingly, problems associated with accessing the accessible registers by anyone other than the client may be prevented by locking the access of the accessible registers using the processes described above.

The access signal generator 164 may be configured to compare a register address input from the address interface 162A with accessible register address information stored in a specific register 166P of the register group 166. The access signal generator 164 may output a third signal indicating access is allowed or a fourth signal indicating access is blocked to the register control circuit 165 based on a result of comparing the input register address and the accessible register address information. In particular, when the input register address matches the accessible register address information, the access signal generator 164 may output the third signal, and when the input register address does not match the accessible register address information, the access signal generator 164 may output the fourth signal.

In example embodiments, the access signal generator 164 may receive the accessible register address information from the specific register 166P by the register control circuit 165. For example, the accessible register address information may include an initiating address N and an ending address M of an address range, as shown in FIG. 4, but embodiments are not limited thereto.

The register control circuit 165 may be configured to control operations of the accessible registers based on signals input from the locking controller 163 and the access signal generator 164. The register control circuit 165 may control the specific register 166P of the register group 166 to transmit the accessible register address information to the access signal generator 164.

In example embodiments, the register control circuit 165 may control the register group 166 to perform a read operation or a write operation of the accessible register based on the register access command input from the command interface 162C and the register address input from the address interface 162A when the first signal indicating that access of the accessible register is permitted is received from the locking controller 163 and the third signal indicating that access is allowed is received from the access signal generator 164.

The register control circuit 165 may determine whether the register access command received from the command interface 162C is a register read command or a register write command.

If the register access command received from the command interface 162C is a register read command, the register control circuit 165 may control the register group 166 to read the set value stored in the accessible register corresponding to the register address received from the address interface 162A. The register control circuit 165 may output the read set value to the logic data interface 162D.

If the register access command received from the command interface 162C is a register write command, the register control circuit 165 may control the register group 166 to change the set value stored in the accessible register corresponding to the register address received from the address interface 162A into a new set value input from the logic data interface 162D.

The register control circuit 165 may perform the read operation or the write operation of the accessible register only when the access allowance signals are received from the locking controller 163 and the access signal generator 164. The register control circuit 164 may not perform an output operation or a change operation of the register information stored in the accessible register to the outside of the memory device 100 via the input/output circuit 170 when an access block signal is received from at least one of the locking controller 163 and the access signal generator 164. In other words, the register control circuit 164 may not output or change register information stored in the accessible register from the memory device 100 when the locking controller 163 or the access signal 164 transmits a block signal to the input/output circuit 170.

The register group 166 may include a plurality of registers configured to store the set values used for various operations of the memory device 100. The register group 166 may include a plurality of first registers or accessible registers 166A that allow the set value to be changed, a plurality of second registers or non-accessible registers 166N that do not allow the set value to be changed, and the specific register 166P that stores address information for a preselected accessible register. In example embodiments, the accessible register may be at least one of the first registers 166A.

The terms “accessible register” and “non-accessible register” in the present disclosure may refer to the general state of a register, e.g. whether a register may be accessed under certain conditions. In particular, it may be possible to change set values stored by an accessible register 166A when access is not blocked, but it may not be possible to change set values stored in a non-accessible register 166N. Alternatively, these registers may be referred to as open and closed registers.

Further, in example embodiments, during the manufacturing stage or the testing stage of the memory device 100, at least one first register including a desired function per the client may be selected as the accessible register. The address information of the selected accessible register may be stored as non-volatile data in a specific region (or block) of the memory cell array 110. The address information of the accessible registers stored in the specific region of the memory cell array 110 may be loaded into the specific register 166P of the register group 166 from the specific region of the memory cell array 110 when the memory device 100 is powered on.

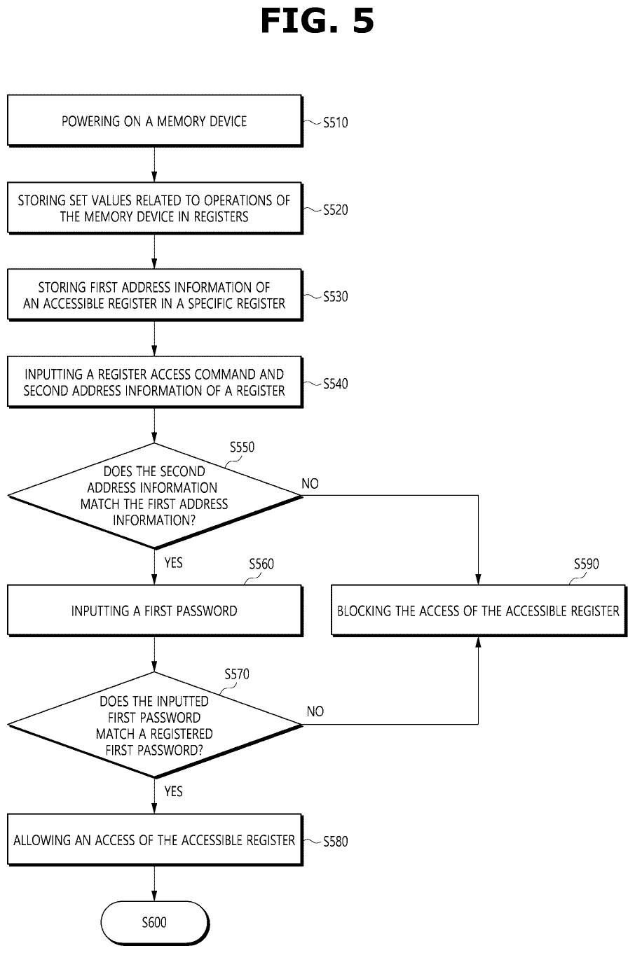

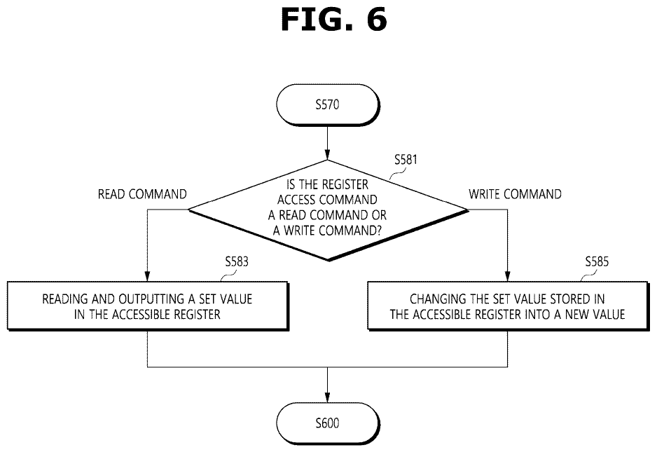

FIG. 5 is a flow chart illustrating an embodiment of a method of operating a memory device, and FIG. 6 is a flow chart illustrating detailed steps associated with step S580 in FIG. 5. In describing the method of operating the memory device based on example embodiments with reference to FIGS. 5 and 6, reference may be made to at least one of the drawings illustrated in FIGS. 1 to 4.

In step S510, the memory device 100 may be powered on.

In step S520, the memory device 100 may store set values of various operations of the memory device 100 in a plurality of registers. For example, the memory device 100 may read the set values stored in the specific region (or block) of the memory cell array 110 and store the read set values in the registers.

In step S530, the memory device 100 may store first address information for the accessible register in a specific register. For example, the accessible register may be a register corresponding to a function for which the client requires the set value to be changed.

In step S540, the memory device 100 may determine whether a register access command and second address information for the register to be accessed is received (input) from an external device. If it is determined that the register access command and the second address information have been received, the process may proceed to step S550.

In step S550, the memory device 100 may determine whether the second address information provided from the external device matches the first address information stored in a specific register. If the second address information matches the first address information, the process may proceed to step S560. On the other hand, if the second address information does not match the first address information, the process may proceed to step S590.

At step S560, the memory device 100 may receive a first password for the accessible register provided from the external device. The “first password” may be a preset or registered password hard coded during a manufacturing stage or a test stage. For example, the ‘first password’ may be an ‘initial password’. Once the first password is received, the process may proceed to step S570.

In step S570, the memory device 100 may determine whether the first password received from the external device matches the registered first password. If the input first password does not match the registered first password, the process may proceed to step S590. Alternatively, if the inputted first password matches the registered first password, the process may proceed to step S580.

In step S580, the memory device 100 may allow access of the accessible register. In an embodiment, referring to FIG. 6, the step S580 of allowing the accessible register to be accessed may include determining whether the received register access command provided from the external device is a read command or a write command (S581). If the received register access command is determined to be the read command, the memory device 100 may read out the set value stored in the accessible register and output the read set value to the external device (S583). If the received register access command is determined to be the write command, the memory device 100 may change the set value stored in the accessible register to a new set value input from the external device (S585).

In step S590, the memory device 100 may block access to the accessible registers. The process may terminate at step S600.

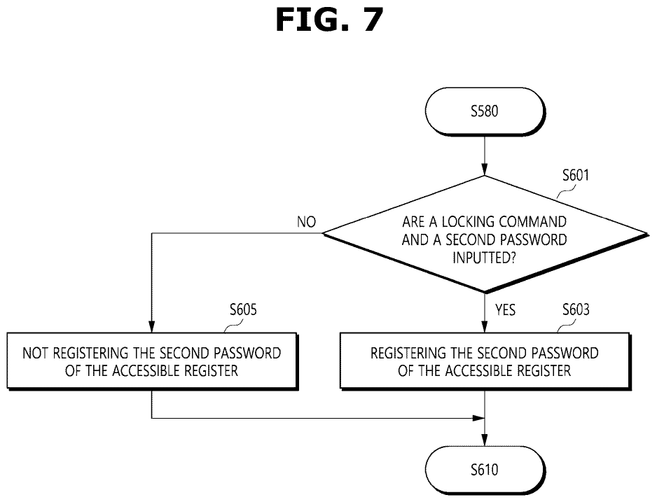

FIG. 7 is a flow chart illustrating a method of locking an accessible register by a client according to an exemplary embodiment.

In step S601, the memory device 100 may determine whether a locking command and a second password to be registered are received (input) from an external device. If the locking command and the second password are received, the process may proceed to step S603. On the other hand, if the locking command and the second password are not received, the process may proceed to step S605.

In step S603, the memory device 100 may register the input second password as the second password for the accessible register.

In step S605, the memory device 100 may not register the second password for the accessible register.

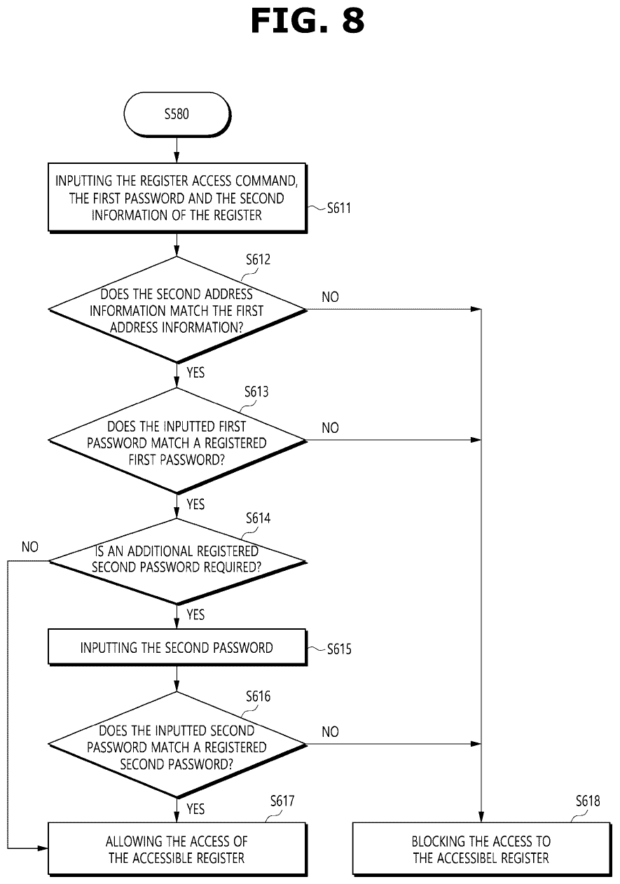

FIG. 8 is a flow chart illustrating a method of accessing an accessible register according to an exemplary embodiment.

In step S611, the memory device 100 may receive a register access command, at least one password and second address information for a register to be accessed from an external device. When the register access command, the password and the second address information have been received, the process may proceed to step S612.

In step S612, the memory device 100 may determine whether the second address information matches the first address information for the accessible register. If it is determined that the second address information matches the first address information, the process may proceed to step S613. On the other hand, if it is determined that the second address information does not match the first address information, the process may proceed to step S618.

In step S613, the memory device 100 may determine whether the input first password and the registered first password match each other. If it is determined that the inputted first password matches the registered first password, the process may proceed to step S614. On the other hand, if it is determined that the input first password does not match the registered first password, the process may proceed to step S618.

In step S614, the memory device 100 may determine whether an additional registered second password is required. The second password may refer to an additional password for an accessible register set and registered by the client. If it is determined that the second password is required, the process may proceed to step S615. On the other hand, if it is determined that the second password is not required, the process may proceed to step S617.

In step S615, the memory device 100 may receive a second password input from the external device.

In step S616, the memory device 100 may determine whether the input second password and the registered second password match. If it is determined that the input second password and the registered second password match, the process may proceed to step S617. On the other hand, if it is determined that the input second password and the registered second password do not match, the process may proceed to step S618.

In step S617, the memory device 100 may allow access of the accessible registers. Embodiments of accessing the accessible registers has been previously described in detail with reference to FIG. 6, and is therefore omitted here.

In step S618, the memory device 100 may block access of the accessible registers.

It is to be understood that the embodiments described above are exemplary and not limiting in all respects, as those skilled in the art to which the invention belongs will recognize that the invention may be practiced in other specific forms without altering its technical ideas or essential features. The scope of the invention is indicated by the following patent claims rather than by the detailed description above, and all modifications or variations derived from the meaning and scope of the claims and their equivalents are to be construed as being within the scope of the invention.

What is claimed is:

1. A memory device comprising:
a memory cell array;
a register group including a plurality of registers configured to store set values used for operations of the memory cell array, the plurality of registers comprising a specific register including first address information of at least one accessible register selected from the plurality of registers; and
a logic controller configured to compare second address information to the first address information, and to allow or block access of the accessible register based on the comparison result,
wherein the second address information is input with a register access command from an external device.

2. The memory device of claim 1,
wherein the register access command is a read command, and
wherein the logic controller is further configured to read out the set value stored in the accessible register and output the set value to the external device when the first address information matches the second address information.

3. The memory device of claim 1,
wherein the register access command is a write command, and
wherein the logic controller is further configured to change the set value stored in the accessible register to a new set value input from an external device, when the first address information matches the second address information.

4. The memory device of claim 3,
wherein the logic controller is further configured to lock access of the accessible register using a password received from the external device, after changing the set value stored in the accessible register to the new set value.

5. The memory device of claim 1,
wherein the logic controller comprises:
a locking controller configured to output a first signal for allowing or blocking access of the accessible register using a password authentication process; and
an access signal generator configured to compare the first address information with the second address information, and to output a second signal for allowing or blocking access of the accessible register based on the comparison result.

6. The memory device of claim 5, further comprising:
a register control circuit configured to control operations of the accessible registers based on the first and second signals provided from the locking controller and the access signal generator.

7. The memory device of claim 6,
wherein the register control circuit is configured to control the register group to perform a read operation or a write operation of the accessible registers, when the first and second signals are provided from the locking controller and the access signal generator, and
wherein the first and second signals indicate whether access of the accessible register is permitted.

8. The memory device of claim 6,
wherein the register control circuit is further configured to control the register group to transmit the first address information of the specific register to the access signal generator.

9. The memory device of claim 1,
wherein the plurality of registers comprises a plurality of first registers, and a plurality of second registers,
wherein the set values of the first registers are changeable, and the set values of the second registers are not changeable, and
wherein the accessible register is included in the first registers.

10. The memory device of claim 1,
wherein the first address information comprises an initiating address and an ending address of an address range corresponding to the accessible register.

11. A method of operating a memory device, the method comprising:
reading set values used for operations of the memory device from a memory cell array and storing the set values in a plurality of registers;
storing first address information of at least one accessible register of the plurality of registers in a specific register;
comparing the first address information with second address information when a register access command and the second address information are received from an external device; and
allowing or blocking access of the accessible register based on the comparison result.

12. The method of claim 11,
wherein the register access command is a read command, and
wherein the logic controller reads out the set value stored in the accessible register and outputs the set value to the external device when the first address information is matched with the second address information.

13. The method of claim 11,
wherein the register access command is a write command, and
wherein the logic controller changes the set value stored in the accessible register to a new set value input from an external device when the first address information is matched with the second address information.

14. The method of claim 13, further comprising:
locking the first address information by registering a password provided from the external device, after changing the set value stored in the accessible register to the new set value.

15. The method of claim 14, further comprising, after locking the first address information:
comparing a password provided from the external device with the registered password; and
allowing or blocking the access of the accessible register based on the comparison result.

16. The method of claim 15,
wherein at least one of a read operation and a write operation of the accessible registers is performed when a password provided from the external device is matched with the registered password, and the first address information is matched with the second address information.

17. A memory device comprising:
a register group including a plurality of registers configured to store set values used for operations of the memory device, and a specific register including first address information of at least one accessible register of the plurality of registers; and
a logic controller configured to compare the first address information with second address information, and to allow access of the accessible register, when the first address information matches the second address information,
wherein the second address information is input with a register access command provided from an external device.

18. The memory device of claim 17,
wherein the logic controller is configured to compare a first password with a second password, and to allow the access of the accessible register when the first password is matched with the second password,
wherein the first password is provided from the external device, and the second password is a registered password.
